(19) United States
(12) Patent Application Publication
(10) Pub. No.: US 2009/0029286 A1
(43) Pub. Date: Jan. 29, 2009

(54) Method for Fabricating Photoresist Pattern

(76) Inventor: Jae Hyun Kang, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/176,439

(22) Filed: Jul. 21, 2008

(30) Foreign Application Priority Data
Jul. 23, 2007 (KR) 10-2007-0073329

(51) Int. Cl. G03F 7/004

(52) U.S. Cl. 430/270.1

(57) ABSTRACT

Disclosed is a method for fabricating a photoresist pattern. The method includes coating photoresist on an etch target layer, forming an initial photoresist pattern through an exposure process using a mask, and growing the initial photoresist pattern to form a final photoresist pattern by using an application of a photoresist material including a reactive organic material.

### CROSS-REFERENCE TO RELATED APPLICATION

The present application claims the benefit of priority under 35 U.S.C. §119 of Korean Patent Application No. 10-2007-0073329, filed Jul. 23, 2007, which is hereby incorporated by reference in its entirety.

### BACKGROUND

In order to manufacture a semiconductor device having a micro-design rule of several tens of nanometers, for example, 50 nm to 60 nm, a photolithography process suitable for various RETs (Resolution Enhancement Technologies) is required.

For example, a photoresist pattern having a micro-design rule may be directly formed by using a PSM (Phase Shift Mask) and an ArF (Argon Fluoride) light source according to a CPL (Chromeless Phase Lithography) technology.

The ArF light source has a short wavelength of about 193 nm. When the ArF light source is used for immersion-type equipment, since the wavelength of the ArF light source may be more shortened due to the refractive index of pure water, a photoresist pattern having a micro-design rule can be formed.

In addition, a double exposure technology using a binary mask and an alternating PSM may be used.

However, since the above technologies require high-priced exposure equipment and a high-priced mask having a high numerical aperture (NA), the manufacturing process is complex and the failure rate is high.

In addition, immersion-type ArF exposure equipment has a price corresponding to about five times the price of KrF (Krypton Fluoride) exposure equipment, and a CPL mask requires the manufacturing cost corresponding to ten times that of the a typical mask.

Particularly, since manufacturing the CPL mask is very difficult, and the CPL mask has a high defect rate, the CPL mask is not readily used to realize the semiconductor device.

### BRIEF SUMMARY

Embodiments of the present invention provide methods for fabricating a photoresist pattern having a micro-design rule by using typical exposure equipment and a typical exposure mask without special-functioned high-priced equipment.

In addition, an embodiment provides a method for fabricating a photoresist pattern capable of using an easily manufactured mask, reducing the probability for a defect occurring on the mask, and employing a KrF process, thereby ensuring a stable process margin and realizing a micro-design rule.

According to an embodiment, a method for fabricating a photoresist pattern comprises coating a photoresist on an etch target layer, performing an exposure process with respect to the photoresist using a mask to form an initial photoresist pattern, and growing the initial photoresist pattern to form a final photoresist pattern, where growing the initial photoresist includes applying a photoresist material comprising a reactive organic material.

### BRIEF DESCRIPTION OF THE DRAWINGS

FIG. 1 is a view showing a layout of a PSM according to an embodiment;

FIG. 2 is a cross-sectional view showing photoresist subject to a lithography process using a PSM;

FIG. 3 is a cross-sectional view showing an initial photoresist pattern according to an embodiment;

FIG. 4 is a view showing the growth of an initial photoresist pattern according to an embodiment; and

FIG. 5 is a cross-sectional view showing a semiconductor substrate after a final photoresist pattern is formed according to an embodiment.

### DETAILED DESCRIPTION

Hereinafter, a method for fabricating a photoresist pattern according to an embodiment will be described with reference to the accompanying drawings.

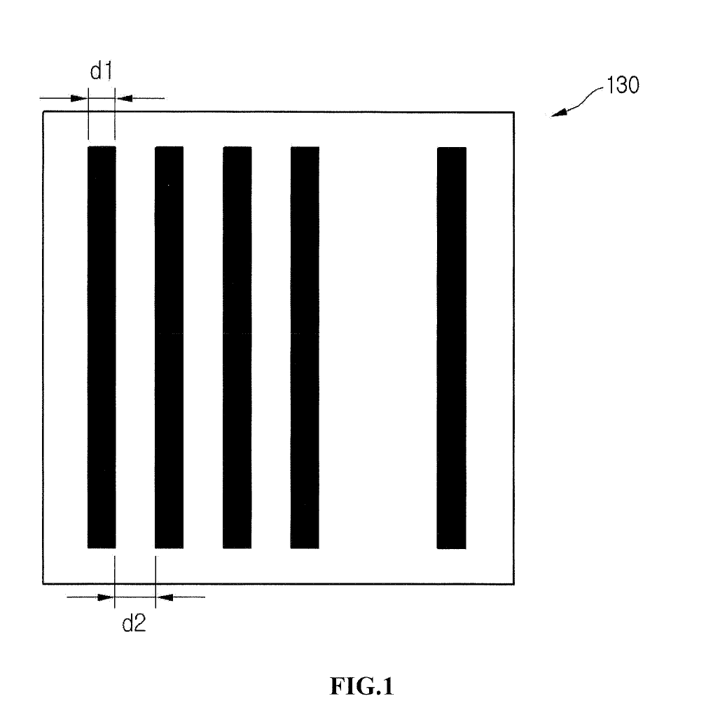

FIG. 1 is a view showing a layout of a PSM (Phase Shift Mask) 130 according to an embodiment.

Through a method for fabricating the photoresist pattern according to embodiments of the present invention, a micro-design rule can be realized in the range of, for example, about 50 nm to about 60 nm. In addition, the photoresist pattern formed according to an embodiment is adaptable for use in patterning the overall structure of a semiconductor device including a semiconductor layer such as a gate electrode or a metal interconnection.

The layout of the PSM 130 shown in FIG. 1 corresponds to an example of a final structure of an object to be etched. According to an embodiment, the line width (d1) of the pattern of the PSM and the interval (d2) between patterns of the PSM can both be 65 nm for the purpose of the description.

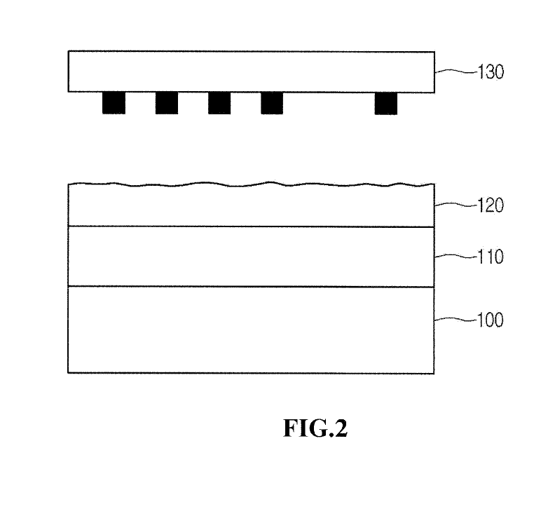

Referring to FIG. 2, a material layer 110 can be formed on a semiconductor substrate 100. The material layer 110 can be referred to as an etch target layer. That is, a layer to be etched. The material layer 110 can be, for example, an insulating layer, a metal layer, or other device layer to be etched.

As described above, although the methods for fabricating the photoresist pattern are adaptable for fabricating the overall structure of a semiconductor device, it is illustrated for the purpose of explanation that the semiconductor substrate 100 is provided thereon with a metal layer 110, where the metal layer 110 is realized as a gate electrode through an etching process.

Accordingly, a photoresist 120 can be coated on the metal layer 110.

According to an embodiment, the photoresist 120 can be formed to a thickness of about 150 nm. Then, the photoresist 120 can be subject to an exposure process using the PSM 130. The PSM 130 can have a phase dampening effect of about 6% to about 10%. In one embodiment, the PSM 130 has a phase dampening effect of about 6%.

When light is incident onto micro-patterns of the PSM 130, light diffraction occurs, so that the path of the light having passed through the micro-patterns is changed. Therefore, the path of the light must be compensated by making destructive interference for the light diffracted into a light blocking area, and constructive interference for the light having passed through a light transmittance area.

In order to adjust the path of the light, a plurality slits capable of shifting the phase can be formed between patterns of the PSM 130.

According to an embodiment, when exposing the photoresist 120, a KrF light source can be used. Therefore, the PSM 130 can be used for a KrF exposure process.

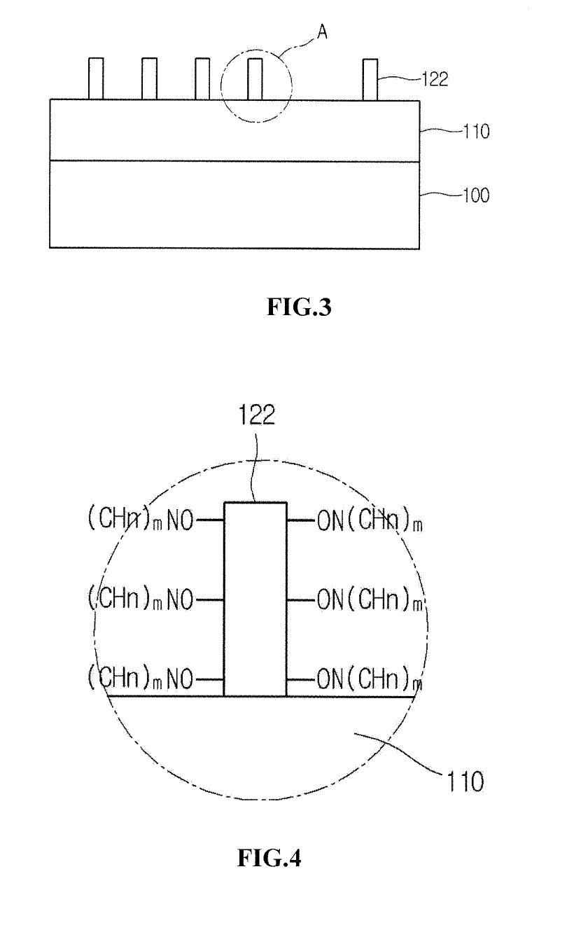

Referring to FIG. 3, the KrF exposure process using the PSM 130 reduces the thickness of the photoresist 120, and an excessive exposure process is performed through the PSM 130, so that the initial photoresist pattern 122 is formed.

Accordingly, due to excessive exposure, the thickness of the initial photoresist pattern 122 is reduced to about 80 nm from the original coating thickness of about 150 nm, and the line width of the initial photoresist pattern 122 is significantly narrowed to about 40 nm from the 65 nm line width assigned to (d1) in this example.

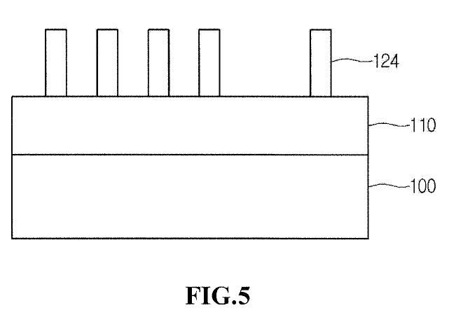

The line width of about 40 nm is less than the line width of a final photoresist pattern 124 (see FIG. 5), and can be achieved because the photoresist 120 has a thickness of about 150 nm.

This is based on the principle in which the resolution of a line width is improved as the thickness of the line width becomes thin.

Meanwhile, in order to allow a photoresist pattern to serve as an etch barrier during an etching process, an aspect ratio (the ratio of a thickness to a line width) should be more than 3:1.

Accordingly, the photoresist 120 for a line width of 65 nm, the photoresist 120 should have a thickness of at least about 200 nm (providing the aspect ratio of more than 3:1). Currently, in order to realize a micro-line width while satisfying a thickness condition of 200 nm or more, high-priced special equipment such as ArF immersion-type exposure equipment are used.

However, advantageously, according to embodiments of the present invention, the high-priced special equipment is not necessary. Instead, according to embodiments, the photoresist pattern can be divided into an initial photoresist pattern 122 and a final photoresist pattern 124. The initial photoresist pattern 122 can be formed using the minimum thickness available to form an initial line width, which is narrower than a target line width, regardless of the thickness condition required for providing an etch barrier.

Thereafter, in the process of forming the final photoresist pattern 124, the target line width can be realized while satisfying the thickness condition. That is, the final photoresist pattern 124 is created to have a thickness that meets or exceeds the aspect ratio. Therefore, the final photoresist pattern 124 according to embodiments can have a micro-line width and an anti-etch property.

For reference, since the initial photoresist pattern 122 can have an aspect ratio of about 2:1, problems such as pattern collapse do not occur, and a stable pattern can be maintained until the final photoresist pattern 124 is formed.

As described above, if the initial photoresist pattern 122 has a line width (about 40 nm in this example) narrower than a target line width without satisfying the thickness condition for anti-etch property, the following process can be performed to form the final photoresist pattern 124.

FIG. 4 is a view showing the growth of an initial photoresist pattern 122 according to an embodiment.

To increase the width and thickness of the initial photoresist pattern 122, a resist material comprising a reactive organic material such as an OH group and amine having strong reactivity is coated on the substrate 100 having the initial photoresist pattern 122, and then the resultant structure is heated. Using the adjusted temperature, the reactive organic material selectively reacts with the initial photoresist pattern 122 such that the initial photoresist pattern 122 grows.

FIG. 4 is an enlarged view of “A” area shown in FIG. 3. As shown in FIG. 4, a resist material including a reactive organic material (ON(CHₙ)ₘ, where n and m are each natural numbers) reacts only with the photoresist initial pattern 122, so that the photoresist initial pattern 122 can be grown.

In this case, where the etch target layer is a metal layer 110, the reaction is induced on exposed regions of the metal layer 110 and the initial photoresist pattern 122. Because a reactive group does not exist in a remaining (exposed) area except for where the initial pattern is provided, the growth of the reactive organic material is inhibited from occurring in areas outside the initial pattern. Accordingly, an anti-reflection film does not need to be provided on the metal layer 110 to form the final photoresist pattern.

In addition, in certain embodiments, the reactive organic material can be injected into a chamber from the upper portion of a reactive tube, such that the reaction more actively occurs on the top surface of the initial photoresist pattern 122 as compared with the side surface of the initial photoresist pattern 122. Accordingly, the thickness of the initial photoresist pattern more quickly grows than the line width of the photoresist pattern.

Then, for this example, if the initial photoresist pattern 122 grows to a thickness of about 200 nm and a line width of about 65 nm, the above reaction can be stopped by lowering the reaction temperature.

In such a manner, the final photoresist pattern 124 with a thickness and a micro-line width having etching resistance can be completed as shown in FIG. 5. Then, an etching process can be performed by using the final photoresist pattern 124, so that a structure, such as a gate electrode for this example, having a line width of about 65 nm can be formed.

Through a method for fabricating a photoresist pattern according to the described embodiment, a semiconductor device, such as a flash memory device having a reflective line structure, requiring a pattern for a micro-pattern can be easily manufactured, and a product yield can be improved.

The effects of methods for fabricating the photoresist pattern according to one or more embodiment are as follows.

First, a photoresist pattern having a micro-line width of 65 nm or less can be fabricated through a KrF process using a typical PSM without high-priced equipment having special functions.

Second, expensive exposure equipment and mask are not required and the mask can be easily manufactured, so that the manufacturing cost can be reduced. In addition, process efficiency can be improved, and a failure rate can be reduced.

Third, a process margin can be stably ensured due to the use of a KrF process, and a threshold line width and a threshold thickness of a photoresist pattern can be easily adjusted by using a reactive group.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a photoresist pattern, comprising:
applying photoresist on an etch target layer;
performing an exposure process using an exposure mask with respect to the photoresist to form an initial photoresist pattern; and
performing a growth process with respect to the initial photoresist pattern to form a final photoresist pattern, wherein performing the growth process comprises applying a photoresist material comprising a reactive organic material.

2. The method according to claim 1, wherein performing the growth process further comprises adjusting a process temperature after applying the photoresist material.

3. The method according to claim 1, wherein the reactive organic material comprises an OH reactive group and amine having strong reactivity.

4. The method according to claim 1, wherein the photoresist material comprising the reactive organic material comprises ON(CHₙ)ₘ where n and m are each natural numbers.

5. The method according to claim 1, wherein the exposure mask is a phase shifting mask.

6. The method according to claim 5, wherein the phase shifting mask has a phase dampening effect in a range of about 6% to about 10%.

7. The method according to claim 1, wherein performing the exposure process comprises using KrF exposure equipment.

8. The method according to claim 1, wherein during performing the growth process the initial photoresist pattern is grown to a thickness in a range of 190 nm to 210 nm and a line width in a range of 50 nm to 70 nm.

9. The method according to claim 1, wherein the final photoresist pattern is formed without using an anti-reflection film.

10. The method according to claim 1, wherein the etch target layer comprises an insulating layer.

11. The method according to claim 1, wherein the etch target layer comprises a metal layer.

12. The method according to claim 1, wherein the pattern line width of the mask and the interval between the patterns of the mask are same.

13. The method according to claim 1, wherein during performing of the exposure process the thickness and the line width of the initial photoresist pattern are determined by adjusting a time of the exposure process with respect to the photoresist.

14. The method according to claim 1, wherein the ratio of thickness to line width of the initial photoresist pattern is at least 2:1.

15. The method according to claim 1, wherein the ratio of thickness to line width of the final photoresist pattern is at least 3:1.

16. The method according to claim 1, wherein the photoresist is applied to a thickness in a range of about 140 nm to about 160 nm.

17. The method according to claim 1, wherein the initial photoresist pattern is formed to have a thickness in a range of about 70 nm to about 90 nm and a line width in a range of about 30 nm to about 50 nm.
